(19) United States
(12) Patent Application Publication
(10) Pub. No.: US 2011/0051385 A1
(43) Pub. Date: Mar. 3, 2011

(54) HIGH-DENSITY MEMORY ASSEMBLY

(75) Inventor: Wei-hu Koh, Irvine, CA (US)

(73) Assignee: Gainteam Holdings Limited, Tsing Yi (HK)

(21) Appl. No.: 12/550,939

(22) Filed: Aug. 31, 2009

(51) Int. Cl. H05K 7/00; B23P 11/00

(52) U.S. Cl. 361/783; 29/428

(57) ABSTRACT

High-density memory assemblies and related methods for manufacturing and using such memory assemblies are included in the present disclosure. According to one exemplary embodiment, a high-density memory assembly includes stacked first and second panels. The first and second panels each comprise a substrate and at least one chip disposed on the substrate. The first and second panels each further comprise connecting tabs extending from the substrates of the first and second panels.

### TECHNICAL FIELD

This disclosure relates generally to memory assemblies, and more specifically, to high-density memory assemblies.

### BACKGROUND

Chip-stacking is a technique that allows for increased memory capacity in memory devices (i.e., the memory density in a given space of a memory device). An individual chip stack is made by vertically stacking multiple memory chips, one chip on top of another one. An individual chip stack includes two or more chips, and a plurality of chip stacks may be incorporated into a memory device.

### BRIEF SUMMARY

This disclosure is directed to a high-density memory assembly comprising a first panel and a second panel stacked on the first panel. In one exemplary embodiment, the first and second panels each comprise a substrate, a connecting tab extending outwardly from an edge portion of the substrate, and at least one chip disposed on a first surface of the substrate. The at least one chip is electrically connected to the connecting tab, and the connecting tabs of the first and second panels are mechanically coupled to each other.

In another embodiment, the high-density memory assembly comprises a first panel and a second panel stacked on the first panel along a first direction. The first and second panels each comprise a substrate, a connecting tab extending in a first longitudinal direction outwardly from an edge of the substrate, the first longitudinal direction being substantially orthogonal to the first direction, and at least one chip disposed on a first surface of the substrate, the at least one chip being electrically connected to the connecting tab. The first and second panels are aligned such that the connecting tabs of the first and second panels are offset from each other along a second longitudinal direction, the second longitudinal direction being substantially orthogonal to the first direction. Furthermore, the connecting tabs of the first and second panels are operable flex in the first direction.

In another aspect, a method for manufacturing a high-density memory assembly is provided. In one embodiment, such a method comprises providing at least two panels, with each panel having a substrate, a connecting tab, and at least one chip element. The method further includes connecting the connecting tab of the panels together.

### BRIEF DESCRIPTION OF THE DRAWINGS

FIG. 1 illustrates a conventional chip stack;

FIG. 2 illustrates another conventional chip stack;

FIG. 3 illustrates a first exemplary embodiment of a high-density memory assembly, in accordance with the present disclosure;

FIG. 4 illustrates a second exemplary embodiment of a high-density memory device, in accordance with the present disclosure;

FIG. 5A illustrates a third exemplary embodiment of a high-density memory assembly, in accordance with the present disclosure;

FIG. 5B illustrates a fourth exemplary embodiment of a high-density memory assembly, in accordance with the present disclosure;

FIG. 5B illustrates a fifth exemplary embodiment of a high-density memory assembly, in accordance with the present disclosure;

FIG. 6 illustrate a memory device comprising a high-density memory assembly of the present disclosure;

FIG. 7 is a focused view of a high-density memory assembly, in accordance with the present disclosure;

FIG. 8A is a side view of a high-density memory assembly with tabs in a first flex position, in accordance with the present disclosure;

FIG. 8B is a side view of a high-density memory assembly with tabs in a second flex position, in accordance with the present disclosure;

FIG. 8C is a perspective view of a is a high-density memory assembly connected to a motherboard, in accordance with the present disclosure; and

FIG. 9 is a block diagram illustrating an embodiment of an assembly process of a memory device having stacked panels, in accordance with the present disclosure.

### DETAILED DESCRIPTION

A stack of memory chips with two, four, eight or higher number of individual chips generally suffers from relatively low overall-yield. The concern is particularly acute for wafer-level die stacking. For die-to-die individual stacking, known good dies (KGD) can first be selected and then stacked, thus the finished die stack would have a relatively high yield, albeit sometimes even this is subject to process loss, e.g. one bottom die is broken. For wafer-level stacking, the yield loss can be even greater if the die yield of a wafer is not sufficiently high. For example, if a wafer has a 90% yield of its individual chips, stacking two wafers may results on 0.9×0.9, or only 81% yield, statistically. Stacking four wafers would result in even worse 65.61% yield. Hence, a higher yield stacking method that is easy to manufacture while suffering no significant loss is desired.

Chip-stacking has many process limitations. It is desirable to have precisely aligned chips in a stack, and accordingly, chips are stacked one at a time. For high volume productions, chip stacks are designed to include a large number of chips to satisfy the throughput demands. But the process yield for stacking is likely to decrease with an increase in the number of chips in a stack. Furthermore, if any one chip in a stack is defective or was damaged during the stacking process, the entire stack is scrapped or would be downgraded. It is quite difficult to repair one chip in the stack after the entire stack is assembled.

Accordingly, there is a need for chip stacks that allow for high memory density, but can be more easily manufactured with higher process yield. A high degree of ease of repair and rework would also be desirable, while the manufacturing process and assembly cost remain competitive.

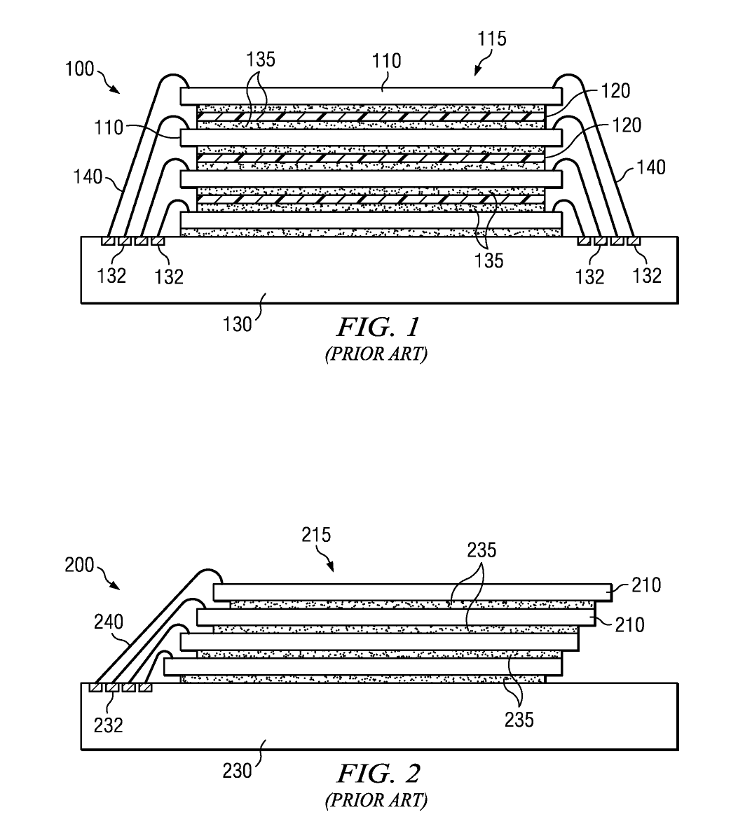

FIG. 1 is a drawing illustrating a conventional memory assembly 100 comprising stacked chips. Individual chips 110 are stacked vertically, and spacers 120 are disposed between the chips 110. The chips 110 and the spacers 120 are laminated together using adhesives 135 to form a chip stack 115. The chip stack 115 is secured on a substrate 130 also using adhesive 135. Wire bonding is used for connecting the input/output pads (not shown) on the chips 110 to contact pads 132 on the substrate 130. Extending from two opposing side portions of the chips 110, the wires 140 are connected to the contact pads 132 of the substrate 130, thereby allowing electrical communication with the chips 110. The spacers 120 are configured to have widths that are generally smaller than that of the chips 110 to provide clearance and allow room for the wires 140 to clear the chip 100 directly above them. While stacking chips vertically allows for increased memory density, the conventional memory assembly 100 has several drawbacks. As shown in FIG. 1, the relatively smaller widths of the spacers 120 leave the edge portions of the chips 110 unsupported, and as such, the edge portions of the chips 110 may be damaged during the wire bonding or other manufacturing processes in which contact has to be made with the edge portions of the chips 110. If the bonding force is too high, cratering, peeling, cracking, or breaking of the chip surface may occur. Moreover, the use of wires 140 to allow electrical communication with the chips 110 may introduce a signal delay, depending on the length of the wire 140.

In some conventional memory assemblies, the spacer 120 is eliminated—reducing the total height and simplifying the chip stacking process. A soft, gel type epoxy may be used in lieu of a spacer on top of the chip after its pads are wire bonded. The gel encapsulates the wire loops and forms a mechanical protection after the gel is cured or solidified. A second chip is then placed on top of the epoxy glue layer and is wire bonded to the substrate. This process may be repeated until the desired number of layers is reached. The gel material used in such convention assemblies, however, are expensive. Moreover, the wait time for the gel to cure and solidify before an additional chip is stacked slows down the assembly throughput.

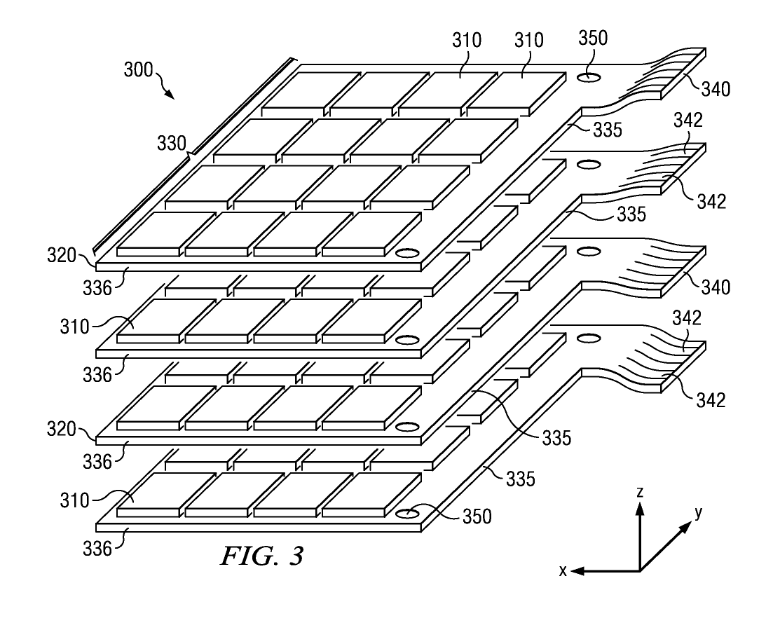

FIG. 2 illustrates a conventional memory assembly 200 having chips 210 stacked and aligned in a stair-step configuration. Given the stair-step alignment of the chips 210, bonding pads (not shown) of each chip 210 are disposed on an exposed side portion of the chip 210 that is not overlapped by another chip 210. Adhesives 235 are disposed between the chips 210 to laminate the chips 210 into a chip stack 215. Adhesives 235 are also used to secure the chip stack 215 on a substrate 230. Extending from the exposed side portion of the chips 210, wires 240 are connected to the contact pads 232 on the surface of the substrate 230.

For assemblies like the conventional memory assembly 200, spacers between the chips 210 are not needed since the stair-step configuration allows the wires 240 to have clearance from next chip. Although the assembly 200 does not have the drawbacks associated with the use of spacers, the stair-step configuration has a number of drawbacks. As each chip 210 is added to the stack in a stair-step configuration, the footprint of the stack increases (i.e., each chip added to the stack increases the footprint area of the chip). The number of chips in a stack is therefore limited by the spatial and other design constraints of a circuit design. For example, as chip stacks are more closely packed relative to each other, the allowable footprint of the chip stacks are decreased due to limited amounted of space on a substrate, and this in turn limits the number of chips that can be accommodated in a chip stack having a stair-step configuration. Additionally, like the wires 140 in conventional memory assembly 100, wires 240 may introduce a signal delay, depending on the length of the wire 240. Furthermore, having all of the wires 240 on one side of each chip 210 results in finer pitches of the wires 240 and bonding pads (i.e., the distance between the wires and between the bonding pads), because all wires are crowded on one side of the chip 210 instead of being spread out on two separate, opposing sides of the chip 210. The crowding of the wires 240 on one side of the chip 210 also could lead to shorts among the wires 240 due to unintended contacts as well as more signal interference and crosstalk due to the proximity of the wires 240.

The conventional memory assemblies discussed above with respect to FIGS. 1 and 2 may have additional drawbacks. As mentioned above, the length of the wire can introduce a signal delay and more crosstalk into the circuit. When chips are stacked on top of each other and are connected to one substrate, each chip will use a different length of wire to connect to the substrate resulting in a different signal delay for each chip. In addition, to ensure that the stack satisfies design and spatial requirements and to ensure that each chip has a good connection with the substrate, precise alignment of the chips is preferred when stacking individual chips. The precise alignment processes, however, can be time-consuming and reduce manufacturing efficiency. Also, when all of the chips are stacked together and connected to one substrate, it is difficult to individually replace the bad chips. For example, if the bottom chip is bad, then all of the chips laminated on top of that chip would need to be removed before the bottom chip could be replaced. This process is time-consuming and impractical.

The present disclosure provides various high-density memory assemblies directed to the use of a plurality of panels that comprises at least one chip. In one embodiment, the panels are coupled, cured, or clamped together for sharing a common connector. The high-density memory assemblies of the present disclosure allow most of the processing of the chips to be completed two dimensionally in the planes of the panels, while the three-dimensional stacking is accomplished by stacking the panels, not the individual chips. As such, the drawbacks of the single die stacks can be avoided, and there is no direct die-to-die contact in a 3-D panel stacking. Such high-density memory assemblies offer superior performance and versatility, and can be used in a variety applications including, but not limited to, high capacity memory modules and flash memory cards.

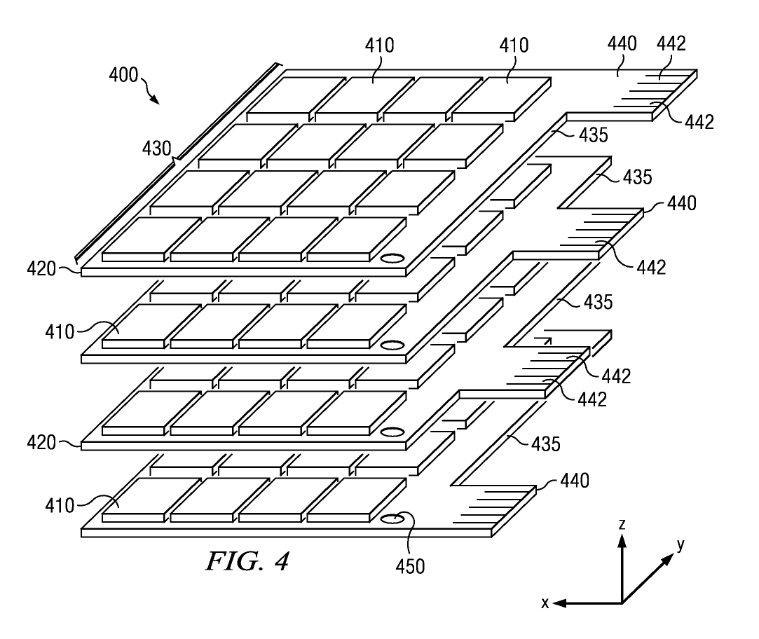

FIG. 3 is a perspective view of an embodiment of a memory assembly 300 in accordance with the present disclosure. The memory assembly 300 comprises a plurality of panels 330, and each panel 330 comprises an array of chips 310 disposed on a thin substrate 320. Chips 310 can be mounted to the substrate 320 by any means known in the art including, but not limited to, flip chip micro bumping with thin underfill materials. Each substrate 320 includes a connecting tab 340 extending outwardly from an edge portion 335 of the substrate, and the tab 340 may be located in any position along the edge portion 335. Each panel 330 includes signal traces (not shown) that are routed to the tab 340, such as the common input/output bus lines and individual chip select or clock lines. To allow electrical contact to another panel or the motherboard of a device, the tab 340 may include two-sided, interconnected gold finger contact pads 342, one on each opposing surface of the tab. A plurality of panels 330 are stacked together to form a “block” memory assembly 300. The panels 330 are aligned at an orientation that allows the connecting tabs 340 to be mechanically coupled to each other.

The panels 330 can be aligned and assembled in a variety of ways including, but not limited to, aligning each layer using fiducial marks (visual marks with no indentation), which may have a variety of configurations. In the embodiment shown in FIG. 3, the fiducial marks are configured to be circular metalized pad markings 350. Fiducial marks may also be cross-shaped or a 90 degree L-shaped surface metal markings defined by photolithograph for precise indication of location. The panels 330 can also be aligned by aligning alignment pin holes on each panel.

According to an embodiment, each panel 330 may be laminated to another panel 330 adjacent to it using adhesive material or using liquid epoxy to fill the gaps between the panels after each panel is stacked. In one embodiment, a thin adhesive spray is applied to at least one surface of a panel 330 to adhesively attach it to another panel 330 adjacent to it. In another embodiment, adhesives are used at certain locations (e.g., the corners of each panel 330) to hold the individual panels 330 in place. Using small dots of adhesives at selected strategic locations to hold the stack 300 together saves assembly time, lowers material and process costs, and allows for easier stacking rework and disassembly. In another embodiment, the panels are connected together by interconnecting the alignment pin holes (not shown).

According to an exemplary embodiment, after a desired number of panels 330 are stacked (e.g., four panels), the memory block assembly 300 is cured and the connecting tabs 340 of the panels 330 are clamped or coupled together by mechanical means. The connecting tabs 340 may also be electrically connected to allow direct communication among all of the panels 330 in the memory assembly 300. In an embodiment, a pin clamp is used to couple the tabs together. In another embodiment, each tab 340 is connected to a receiving contact connector socket onboard a printed wiring board (PWB) or another connector. Coupling the tabs 340 together allows the block memory assembly 300 to be used as a large die stack with its own connector pins. As such, the memory assembly 300 is a functional module and it does not need to be mounted to a rigid base substrate. Obviating the need for a rigid substrate allows the assembly 300 to have a variety of versatile applications, including being used as a flexible, high-capacity memory module or being molded to form a flash memory card.

Besides its versatility, the memory assembly 300 also offers a simpler design, which can help to reduce manufacturing errors and increases efficiency. In an embodiment, a stack of four 2×4 panels 330 can form a single die stack having 32 chips and a common tab with 25 input/output pads (a single group of bonding pads). By comparison, if chips are stacked individually, eight individual stacks of four would be used to achieve the capacity of the above mentioned embodiment. Further, each stack would include 25×4 (or 100) gold wires, for a total of 800 wires for eight stacks. The main board holding the stacks would use eight groups of bonding pads—one for each stack.

It is to be appreciated that the embodiments described herein can be modified according to the principles of the present disclosure. For example, in an embodiment, the tabs 340 are flexible and can be bent or flexed into a variety of positions. According to another embodiment, each panel 330 may contain more than one tab—e.g. one tab on each side, one tab on two sides, or two tabs on one side.

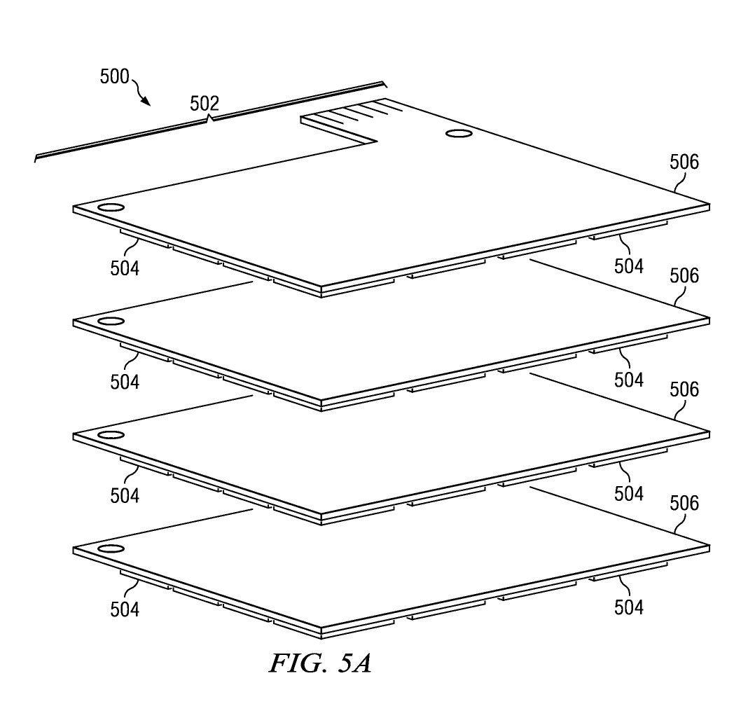

FIG. 4 is a drawing illustrating a perspective view of an embodiment of a multiple chip memory assembly 400. The block memory assembly 400 includes a plurality of panels 430 stacked along a first direction z as shown in FIG. 4. An array of chips 410 is mounted on a thin substrate 420 of a panel 430. According to one embodiment, the stacked panels 430 define a plurality of substantially parallel planes, and the first direction z is substantially orthogonal to the parallel planes.

In some embodiments, the panels 430 include signal traces (the common I/O bus lines and individual chip select or clock lines) that are routed to the tab 440 of the panels 430. The tabs 440 extend in a first longitudinal direction x outwardly from the edge 435 of the substrate 420, and they can be located in any position along the edge 435. As shown in FIG. 4, the first longitudinal direction x is substantially orthogonal to the first direction z. The panels 430 are aligned such that the connecting tabs 440 are offset from each other along a second longitudinal direction y. The second longitudinal direction y is also substantially orthogonal to the first direction z. As such, the connectivity tabs 440 do not overlap end-other in this first direction z.

Aligning the panels can be accomplished in a variety of ways including, but not limited to, aligning each layer using fiducial marks 450 or by aligning alignment pin holes (not shown) on each layer. In FIG. 4, the panels 430 comprise the fiducial marks 450 aligned along the first direction z.

In an embodiment, each tab 440 comprises gold finger contact pads 442 and is operable to be connected to a receiving contact connector or bonding pads on a printed wiring board (PWB). In an exemplary embodiment, the connecting tabs 440 of the first and second panels are operable flex in the first direction z. The connecting tab 440 of one panel 430 may be bent to a flexed position such that some or all of the connecting tabs 440 are substantially level relative to each other. Being level, the connecting tabs 440 of panels 430 may be received in an electrical connector, and in some embodiments, the electrical connector may be operable to provide electrical connection between the connecting tabs 440. In some embodiments, the tab 440 of a first panel 430 may be bent to a first flexed position, and the connecting tab 440 of a second panel 430 may be bent to a second flexed position such that the connecting tabs 440 of the first and second panels 430 are substantially level relative to each other.

Referring to FIGS. 3 and 4, in contrast to conventional necessary assemblies, which include a rigid substrate to provide structural support and electrical contracts, the above discussed configurations of the tabs 340, 440 allow the memory assemblies 300, 400 to operate as an independent memory module without the need for a rigid substrate. Without the constraints of a rigid substrate, the memory assemblies 300, 400 can be configured to have substantial flexibility. For example, each substrate 320, 420 and/or each chip 310, 410 may also be substantially flexible, thereby imparting flexibility to the panels 330, 430. Moreover, flexible tabs 340 and 440 may be easier to clamp together into a connecter. Flexible assemblies can be incorporated into memory devices that are designed to flex. Even for devices that do not require substantial flexibility, flexible memory assemblies 300, 400 are operable to be deformed within the devices to accommodate the internal spatial constraints presented by other components of the devices. Accordingly, the memory assemblies 300, 400 are operable to offer more efficient use of space for miniaturized devices.

It is to be appreciated that the configuration of memory assemblies 300, 400 can be modified to accommodate various needs according to the principles of the present disclosure. For example, in some embodiments, each panel 330, 430 is laminated to form a stacked panel. Using an adhesive for lamination would also providing additional support and protection for the chip elements 310, 410.

In some embodiment, each panel 330, 430 contains an array of identical memory integrated circuit (IC) chips and the stack assembly 300, 400 is placed in an appropriate enclosure or connector to form a high-density, high capacity memory module or cards. In another embodiment, each panel 330, 430 contains an assortment of chips including, but not limited to, memory controllers, passives, logic chips, and memory chips.

The size, shape, and number of each panel 330, 430 can be tailored to fit the desired module capacity, size, and function. For example, a stack 300, 400 with a panel 330, 430 of 35×40 millimeters is used inside of a compact flash (CF) card. A larger stack 300, 400 with panels 330, 430 of 50×70 millimeters is used inside of a 1.8 inch solid-state disk drive.

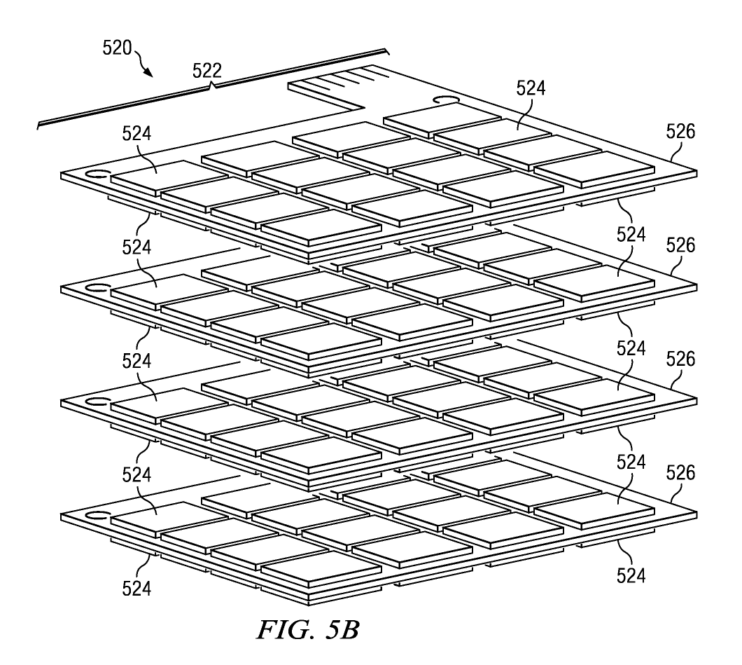

FIGS. 5A-5C are drawings illustrating perspective views of memory assemblies 500, 520, 540. Referring to FIG. 5A, in an embodiment, each panel 502 includes chips 504 on one surface of the substrate 506 (e.g., the top or bottom surface). Referring to FIG. 5B, each panel 522 includes chips 524 on both the top and bottom surfaces of the substrate 526. Referring to FIG. 5C, the top panel 542 includes chips 544 on the bottom surface of the substrate 546; the inner panels 542 include chips 544 on both surfaces of the substrates 546; and the bottom panel 542 includes chips 544 on the top surface of the substrate 546, providing significant mechanical protection for the chips 544. The configuration of the panels 502, 522 and 542 may otherwise be similar to that of panels 330, 430.

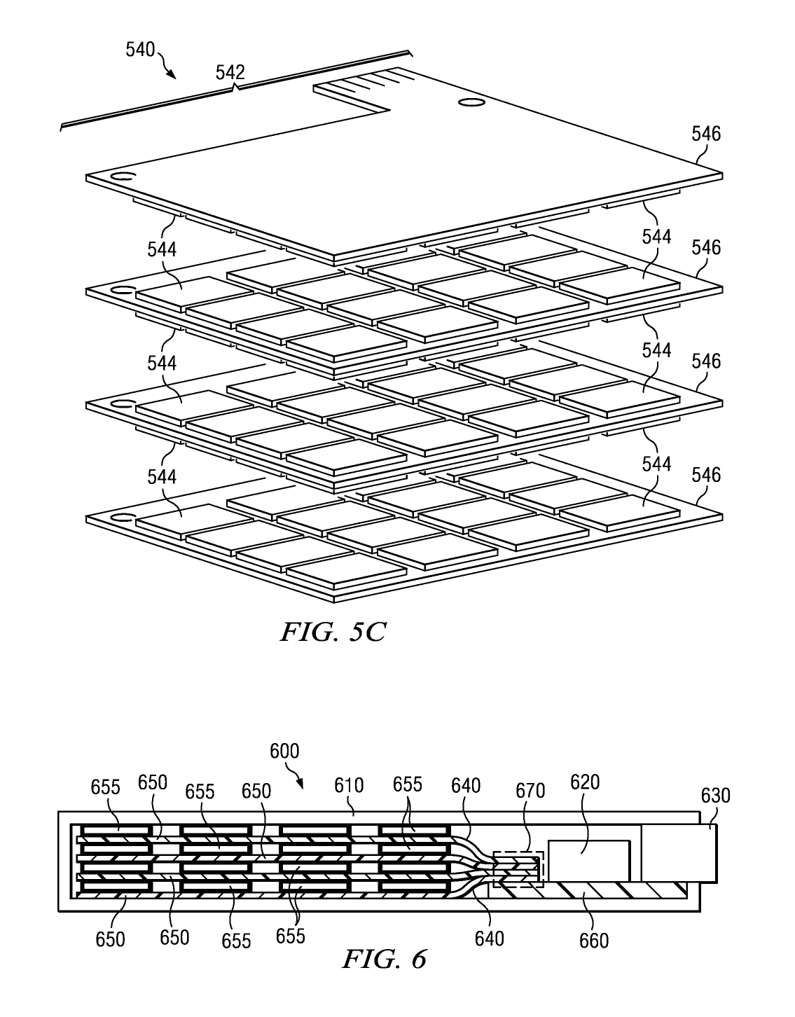

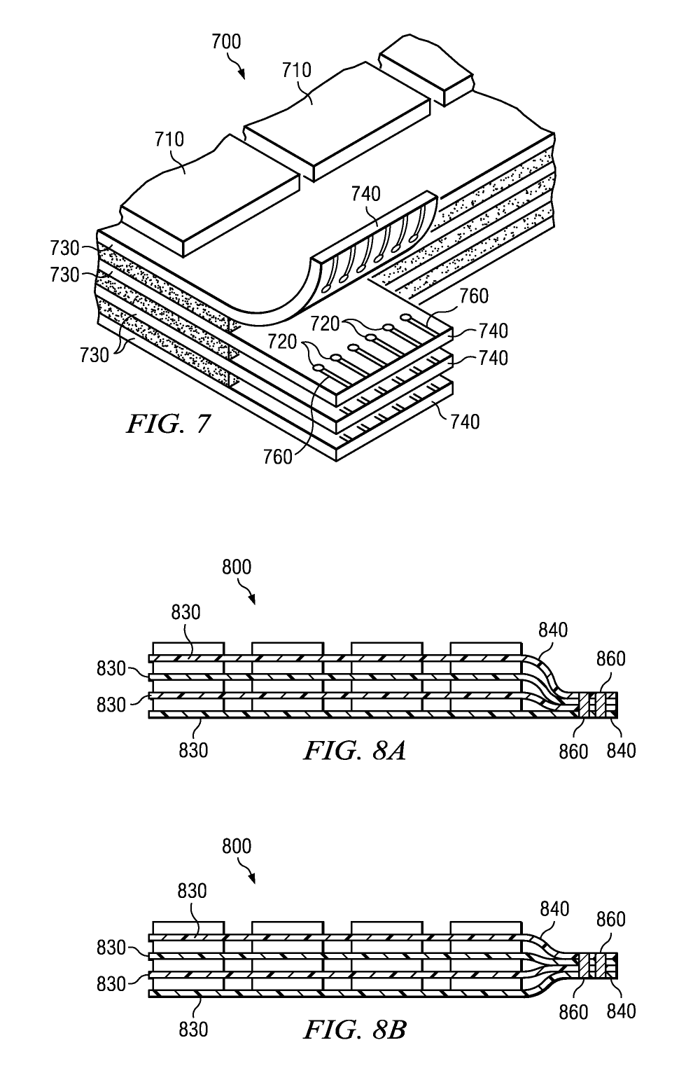

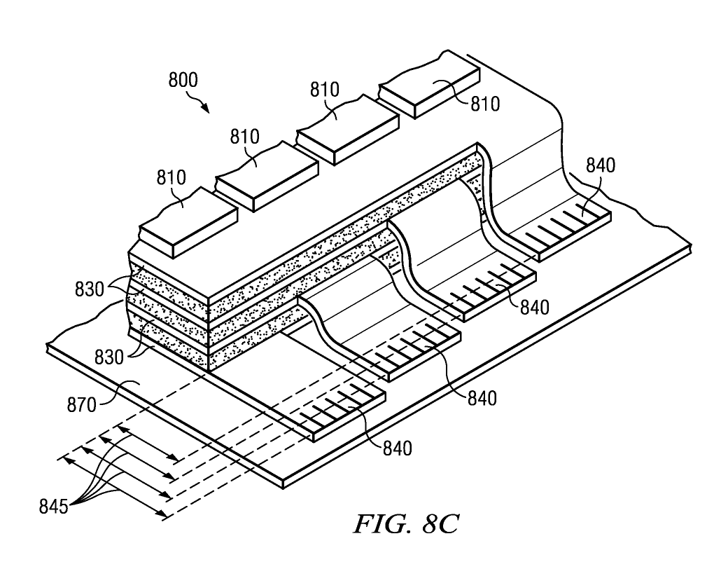

FIG. 6 is a cross-sectional view of an embodiment of a memory device 600 comprising a four-panel memory assembly 605. The device 600 may be any memory devices known in the art, including a USB flash drive, a CF card, or a solid-state disk drive. The assembly 605 is disposed within an enclosure case 610 and comprises panels 650. The panels 650 each comprise a plurality of chips 655 and a tab 640 extending from an edge of the panel 650. The tabs 640 of the panels 650 in the assembly 605 may be constructed according to any of the embodiments described in the present application. For example, as illustrated in FIG. 6, the tabs 640 may be clamped together and inserted into a connector 670, which allows electrical communication to a master controller unit 620 and external connector 630 via a motherboard 660. The motherboard 660 may be any type of main board used in the art, including a printed circuit board. It should be appreciated that in some embodiments, the tabs 640 may be directly connected to the main motherboard 660 without the use of a connector 670. Further description of the connectivity of the tabs in various embodiments is provided with respect to FIGS. 7-8C.

FIG. 7 is a schematic diagram illustrating a memory assembly 700. In an embodiment of the memory assembly 700, each panel 730 includes at least one tab 740. Each tab 740 has gold finger contact pads 760 on both surfaces of the tab 740. In this drawing, only two gold finger contact pads 760 are shown on each surface of each tab 740. This is for illustration purposes only, i.e. each tab 740 may contain any number of gold finger contact pads 760 on each surface of the tab 740. Each tab also includes plated through holes 720 (PTH) for interconnecting the gold finger on the top surface to the ones on the bottom surface of each tab. The tabs 740 can then be clamped or bundled together to form electrical contact between each tab 740. The bundled or clamped group of tabs 740 can then be inserted into a female socket or can be connected to a main motherboard via the top (on the top surface of the top tab 740) or bottom (on the bottom surface of the bottom tab 740) gold finger pads 760 using either solder joints or socket.

FIGS. 8A-8C are schematic diagrams illustrating various embodiments of a memory assembly 800. In these embodiments, the tabs 840 of each panel 830 are operable to be flexed. FIG. 8A shows the tabs 840 bending down towards the bottom-most panel 830. The tabs can be clamped together allowing for electrical connectivity between the plated through holes (similar to those shown in FIG. 7) of adjacent tabs 840. Alternatively, a conductive metal pin (not shown) may be driven into the aligned tabs through the gold finger tabs 860 to form a vertical electrical connection for the tabs 840. The bundled tabs 840, now a single, thicker (and stiffer) tab, can be inserted into a female socket on a motherboard for electrical connection. Alternatively, this thicker tab may be directly soldered onto a motherboard.

Similarly, FIG. 8B illustrates the tabs 840 being flexed towards a center panel 830. The upper tabs are bent downwards (in the z-direction) and the lower tabs are bent upwards (in the z-direction), i.e. the outer tabs are bundled or wrapped around the middle tabs on the middle panels 830. Similar to the embodiment of FIG. 8A, plated through holes (not shown) may provide electrical connection between the gold finger pads 860 on both surfaces of tabs 840. Alternatively, a metal pin (not shown) may be driven through the gold finger pads 860 on the tabs 840 resulting in a vertical electrical connection. The bundled tabs 840, now a single thicker (and stiffer) tab, can be inserted into a female socket on a motherboard for electrical connection. Alternatively, this thicker tab may be directly soldered onto a motherboard.

FIG. 8C illustrates a plurality of panels 830 stacked along a first direction z. An array of chips 810 is mounted on a thin substrate 820 of the panel 830. The tabs 840 extend in a first longitudinal direction x outwardly from the edge 835 of the substrate 820, and they can be located in any position along the edge 835. As shown in FIG. 8C, the first longitudinal direction x is substantially orthogonal to the first direction z. The panels 830 are aligned such that the connecting tabs 840 are offset from each other along a second longitudinal direction y. The second longitudinal direction y is also substantially orthogonal to the first direction z. Each tab 840 may flex up or down in the first direction z and connect to bonding pads on a motherboard 870. Alternatively, each tab 840 may connect into individual female sockets, e.g. if the stack includes four panels 830, then the tabs 840 would connect into four separate socket connectors, which can be configured to allow electrical communication between the tabs 840 themselves and between the tab 840 and the motherboard. It is to be appreciated that due to the thickness of the memory assembly 800, the lengths 845 of the tabs 840 in the flex position may not be the same. To accommodate this, the location of the sockets on the motherboard 870 may be adjusted to correspond to the length 845 of the respective tab 840. Alternative, the tabs 840 may be configured to have different length when the tabs 840 are in the non-flexed position.

Further advantages of some of the embodiments disclosed in the present application are discussed below. Referring to FIGS. 3 and 4, aligning the substrates 320, 420 with precise fiducial marks 350, 450 or precise alignment holes allows for higher precision, easier processing, and higher process yield than individual stacking chips. Prior to clamping the panels 330, 430 together, each panel 330, 430 is electrically independent of the other panels and, thus, it is not necessary to have each individual IC chip aligned precisely with the chip above or below. Hence, the stacking of the panels can be achieved without aligning each individual IC chip, making the stacking easier and more efficient.

In the first step of building a panel, each die may be placed side-by-side using high throughput surface mount equipment, and only KGD (known good dies) may be chosen, so the panel yield is high. After a panel is built, each panel is tested using a tabbed input/output connector to ensure that all chips on the panel are good. If one or more chips test bad, they can be easily replaced because dies are not individually stacked. Therefore, when a group of panels are stacked, all chips on the panels have been tested and are ensured to be good, and consequently that repair afterwards is minimized.

As discussed above, prior to stacking, each panel 330, 430 can be tested thoroughly and if one chip is bad, it is replaced by another good chip before the panel is used for the next assembly step in the stacking process. Every chip 310, 410 can be tested before the final layer stacking. After the panels are stacked together, if one or more chips 310, 410 is found to be bad, disassembly of the block memory assembly 300, 400 is relatively easy and the bad chip may be replaced by removing the bad chip 310, 410 from a panel 330, 430, replacing it with a good chip 310, 410, and reassembling the stack 300, 400 of panels 330, 430.

The assembly and manufacture of some of the embodiments disclosed in the present application are discussed below.

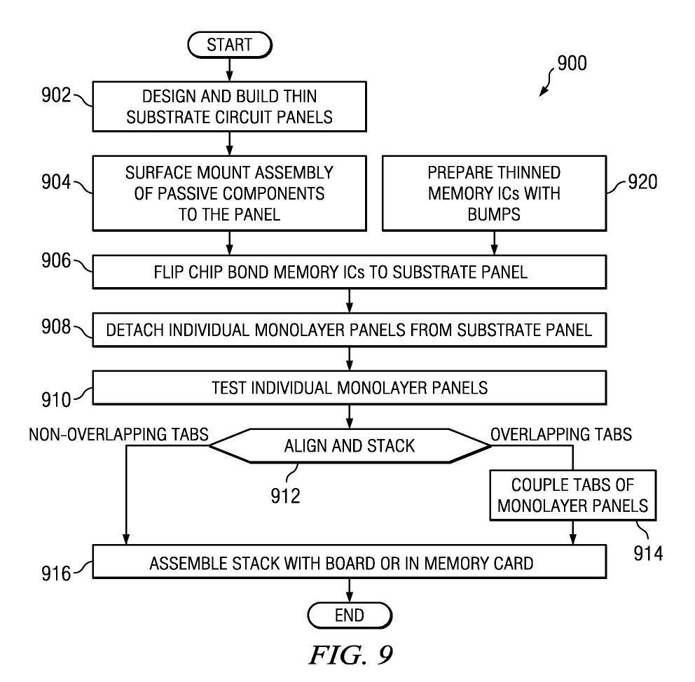

FIG. 9 is a diagram illustrating an embodiment of the assembly process 900 for assembling panels in a memory device. The first step is to design and build thin substrate circuit panels 902. Next, passive components are surface mounted to the substrate panel in step 904. In step 920, preparing thinned memory ICs with bumps can be done any time before step 906. Step 906 includes flip chip bonding the memory ICs (from step 920) with the passive components already mounted to the substrate panel (from steps 902 and 904). Next, individual panels are detached from the substrate panel in step 908. E.g., a substrate panel can be 4×8 inches squared and can contain six individual monolayer layer units, with each unit containing 8 ICs. The individual panel units can be separated from the rest of the substrate panel by cutting, tearing a perforated edge, or any other method known in the art. Next, each panel is tested in step 910. In an embodiment, every panel is tested. In another embodiment, only selected panels are tested. In yet another embodiment, only selected ICs on each panel are tested. After the panels are tested, they are aligned and stacked in step 912. In an embodiment, the aligned panels can be laminated or adhered together during the stacking process according to the principles disclosed in the present disclosure. In some embodiments, the tabs of the panels are coupled together in step 914. Coupling the tabs may include any form of vertical electrical connection including, but not limited to, laminating the tabs together, clamping the tabs together, pinching the tabs together, gluing the tabs together, and disposing metal pins through the stacked tabs. For embodiment in which the tabs are not directly connected, then step 914 is skipped. Lastly, the panel stack is assembled with a board, memory card, socket, or device in step 916. This assembly can include, but is not limited to, inserting aligned tabs of a panel stack into a female socket or enclosing the stack in a case to form a thin memory card.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A high-density memory assembly, comprising:
a first panel; and
a second panel stacked on the first panel, wherein the first and second panels each comprise:
a substrate;
a connecting tab extending outwardly from an edge portion of the substrate; and
at least one chip disposed on a first surface of the substrate, the at least one chip being electrically connected to the connecting tab;
wherein the connecting tabs of the first and second panels are mechanically coupled to each other.

2. The memory assembly of claim 1, wherein the connecting tabs of the first and second panels each comprise at least one gold finger pad and at least one plated through hole, wherein the at least one plated through holes of the first and second panels are operable to provide an electrical connection between the at least one gold finger pads of the first and second panels.

3. The memory assembly of claim 1, further comprising a metal pin coupling the connecting tabs of the first and second panels, the metal pin being operable to provide an electrical connection between the first and second panels.

4. The memory assembly of claim 1, wherein the first and second panels are stacked along a first direction are aligned such that the connecting tabs of the first and second panels are aligned along the first direction, and further wherein, the connecting tabs of the first and second panels are coupled by an electrical connector.

5. The memory assembly of claim 1, wherein the substrates of the first and second panels each comprise at least one fiducial mark, and the first and second panels are aligned such that the at least one fiducial marks of the first and second panels substantially overlap.

6. The memory assembly of claim 1, further comprising a liquid epoxy filler layer disposed between the first and second panels.

7. The memory assembly of claim 1, wherein the substrates of the first and second panels each comprise bus lines, the bus lines extending from the at least one chips of the first and second panels to the connecting tabs of the first and second panels, respectively.

8. The memory assembly of claim 1, wherein the first and second panels and the connecting tabs of the first and second panels are substantially flexible.

9. The memory assembly of claim 1, wherein the first panel comprises an array of chips.

10. The memory assembly of claim 9, wherein the array of chips comprises at least one memory chip and at least one logic chip.

11. The memory assembly of claim 1, wherein the connecting tabs of the first and second panels are electrically connected to each other.

12. The memory assembly of claim 1, further comprising
a motherboard, the connecting tabs of the first and second panels being connected to the motherboard; and
an enclosure housing the first panel, the second panel, and the motherboard.

13. A high-density memory assembly, comprising:
a first panel; and
a second panel stacked on the first panel along a first direction, wherein the first and second panels each comprise:
a substrate;
a connecting tab extending in a first longitudinal direction outwardly from an edge of the substrate, the first longitudinal direction being substantially orthogonal to the first direction; and
at least one chip disposed on a first surface of the substrate, the at least one chip being electrically connected to the connecting tab;
wherein the first and second panels are aligned such that the connecting tabs of the first and second panels are offset from each other along a second longitudinal direction, the second longitudinal direction being substantially orthogonal to the first direction; and further wherein the connecting tabs of the first and second panels are operable flex in the first direction.

14. The memory assembly of claim 13, wherein the connecting tab of the first panel is in a flexed position such that the connecting tabs of the first and second panels are substantially level relative to each other.

15. The memory assembly of claim 14, wherein the connecting tabs of the first and second panels are received in an electrical connector, the electrical connector being operable to provide electrical connection between the connecting tabs of the first and second panels.

16. The memory assembly of claim 13, wherein the connecting tab of the first panel is in a first flexed position, and the connecting tab of the second panel is in a second flexed position such that the connecting tabs of the first and second panels are substantially level relative to each other.

17. The memory assembly of claim 16, wherein the connecting tabs of the first and second panels are received in an electrical connector, the electrical connector being operable to provide electrical connection between the connecting tabs of the first and second panels.

18. The memory assembly of claim 13, wherein the first and second panels are laminated to each other.

19. The memory assembly of claim 13, further comprising
a motherboard, the connecting tabs of the first and second panels being connected to the motherboard; and
an enclosure housing the first panel, the second panel, and the motherboard.

20. A method for manufacturing a memory assembly, the method comprising:
providing a first panel, the first panel comprising a first substrate and a first connecting tab extending outwardly from an edge portion of the first substrate;
disposing at least one chip on a first surface of the first substrate;
providing an electrical connection between the at least one chip of the first substrate and the first connecting tab;
providing a second panel, the second panel comprising a second substrate and a second connecting tab extending outwardly from an edge portion of the second substrate;
disposing at least one chip on a first surface of the second substrate;
providing an electrical connection between the at least one chip of the second substrate and the second connecting tab;
stacking first and second panels; and
coupling, mechanically, the first and second connecting tabs.

21. The method of claim 20, further comprising providing an electrical connector and inserting the first and second connecting tabs into the electrical connector.

22. The method of claim 20, further comprising electrically connecting the first and second connecting tabs.

23. A method for manufacturing a memory assembly, the method comprising:
providing first and second panels;
stacking the first and second panels along a first direction, wherein the first and second panels each comprise a substrate and a connecting tab extending in a first longitudinal direction outwardly from an edge of the substrate, the first longitudinal direction being substantially orthogonal to the first direction;
disposing at least one chip on a first surface of the substrate of each panel, the at least one chip being electrically connected to the connecting tab of each panel; and
aligning the first and second panels such that the connecting tabs of the first and second panels are offset from each other along a second longitudinal direction, the second longitudinal direction being substantially orthogonal to the first direction.

24. The method of claim 23, wherein the connecting tabs of the first and second panels are operable to flex in the first direction, and further wherein the method comprises adjusting the connecting tab of the first panel to a first flexed position such that the connecting tabs of the first and second panels are substantially level relative to each other.

25. The method of claim 23, further comprising providing an electrical connector and inserting the first and second connecting tabs into the electrical connector.

26. The method of claim 23, wherein the connecting tabs of the first and second panels are operable to flex in the first direction, and further wherein the method comprises adjusting the connecting tab of the first panel to a first flexed position and the connecting tab of the second panel to a second flexed position such that the connecting tabs of the first and second panels are substantially level relative to each other.

27. The method of claim 26, further comprising providing an electrical connector and inserting the first and second connecting tabs into the electrical connector.
